(19) United States
(12) Patent Application Publication
(10) Pub. No.: US 2012/0153997 A1
(43) Pub. Date: Jun. 21, 2012

(54) Circuit for Generating a Reference Voltage Under a Low Power Supply Voltage

(75) Inventors: Jean-Pierre Blanc, Theys (FR); Pratap Narayan Singh, Varanasi (IN)

(73) Assignee: STMicroelectronics SA, Montrouge (FR)

(21) Appl. No.: 13/242,508

(22) Filed: Sep. 23, 2011

(30) Foreign Application Priority Data
Dec. 17, 2010 (FR) 10/60730

(51) Int. Cl. H03B 1/00

(52) U.S. Cl. 327/109

(57) ABSTRACT

A circuit for generating a reference voltage including: a first current source in series with a first bipolar transistor, between a first and a second terminal of application of a power supply voltage; a second current source in series with a second bipolar transistor and a first resistive element, between said first and second terminals, the junction point of the first resistive element and of the second bipolar transistor defining a third terminal for providing the reference voltage; a follower assembly having an input terminal connected between the first current source and the first bipolar transistor, and having an output terminal connected to a base of the second bipolar transistor; and a resistive dividing bridge between the output terminal of the follower assembly and said second terminal, the midpoint of this dividing bridge being connected to a base of the first bipolar transistor.

### CROSS-REFERENCE TO RELATED APPLICATIONS

This application claims the priority benefit of French patent application Ser. No. 10/60730, filed Dec. 17, 2010, entitled “Circuit for Generating a Reference Voltage Under a Low Power Supply Voltage,” which is hereby incorporated by reference to the maximum extent allowable by law.

### TECHNICAL FIELD

The present invention generally relates to electronic circuits generating stable reference voltages (Bandgap reference).

The present invention relates to such circuits, be they self-contained or included in an electronic circuit comprising other functions such as, for example, a circuit for reading from a memory or a charge pump regulation circuit.

### BACKGROUND

Generally, a circuit generating a reference voltage of stable “bandgap” type is based on a combination of resistive elements and bipolar transistors. For a given temperature variation, the voltages originating from resistive elements and the voltages originating from bipolar transistors have opposite variations. These voltages are then combined to obtain a reference voltage which is unaffected by temperature variations.

FIG. 1 shows an example of such a reference voltage generation circuit. This circuit comprises the following elements:
a first branch comprising a resistive element R2 in series with a first bipolar transistor Q1, between an output terminal V_{BG} of the circuit and a terminal 20 of application of a reference voltage (typically, ground GND), transistor Q1 being diode-mounted (with its base and collector interconnected);
a second branch, parallel to the first branch, comprising a second bipolar transistor Q2, diode-mounted and in series with two resistive elements R1 and R3, element R3 having the same value as element R2; and
an operational amplifier 12 having one of its input terminals coupled to the junction point of the series assembly of the first branch, the other input terminal being coupled to the junction point of resistive elements R1 and R3 of the second branch, the output terminal of this operational amplifier being coupled to output terminal V_{BG} of the circuit, the operational amplifier being powered by a voltage VDD between a terminal 10 and terminal 20.

Operational amplifier 12 adjusts its output voltage so that the voltages on its two input terminals are equal. Accordingly, transistors Q1 and Q2 conduct the same collector current.

Voltage V₁ across resistor R1 may be written as:

V₁=V_{be1}−V_{be2},

where V_{be1} (respectively V_{be2}) designates the base-emitter voltage of transistor Q1 (respectively Q2).

One may also write:

$${V}_{1} = \frac{kT}{q} ln ( p ) ,$$

where k designates Boltzmann's constant, q designates the electronic charge, T designates the temperature in Kelvin, and p designates the surface area ratio between transistors Q1 and Q2. This expression of voltage V₁ is proportional to temperature T.

Voltage V_{BG} may be written as:

$${V}_{BG} = {V}_{be 1} + \frac{{R}_{2}}{{R}_{1}} \frac{kT}{q} ln ( p ) ,$$

where R1 and R2 designate the respective values of resistors R1 and R2.

By adjusting ratio R₂/R₁, the decrease of voltage Vbe₁ according to temperature is compensated to obtain a reference voltage which is independent from temperature variations.

A disadvantage of known circuits is that the voltage difference (offset) between the input terminals of amplifier 12 (due to the mismatch between the internal components of this amplifier) generates a dispersion of the circuit output voltage. This dispersion adversely affects the accuracy of the generated reference voltage.

Another disadvantage of such a circuit is that it does not operate with a power supply voltage smaller than 1.30 V due to internal voltage drops in the amplifier assembly.

### SUMMARY OF THE INVENTION

In one aspect, the present invention provides for a circuit for generating a reference voltage, comprising a first current source in series with a first bipolar transistor, between a first and a second terminals of application of a power supply voltage, and a second current source in series with a second bipolar transistor and a first resistive element, between said first and second terminals, the junction point of the first resistive element and of the second bipolar transistor defining a third terminal for providing the reference voltage. The circuit further includes a follower assembly having an input terminal connected between the first current source and the first bipolar transistor, and having an output terminal connected to a base of the second bipolar transistor, and—a resistive dividing bridge between the output terminal of the follower assembly and said second terminal, the midpoint of this dividing bridge being connected to a base of the first bipolar transistor.

According to an embodiment, the device further comprises a second resistive element interposed between the output terminal of the follower assembly and the base of the second bipolar transistor.

According to an embodiment, the current sources are formed of MOS transistors mounted as a current mirror.

According to another embodiment, the collector surface area of the second bipolar transistor is larger than the collector surface area of the first bipolar transistor.

According to yet another embodiment, the follower assembly is formed of a current source in series with a MOS transistor.

The foregoing and other objects, features, and advantages will be discussed in detail in the following non-limiting description of specific embodiments in connection with the accompanying drawings.

### BRIEF DESCRIPTION OF THE DRAWINGS

Other features and advantages of the invention will become apparent upon examining the detailed description of non-limiting embodiments and their implementations, and the appended drawings in which:

FIG. 1, previously described, shows the electric diagram of a known architecture for a circuit generating a stable reference voltage;

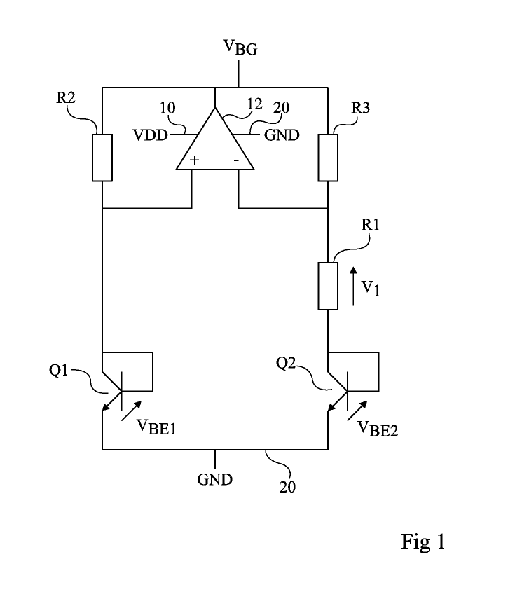

FIG. 2 shows an embodiment of a circuit generating a stable reference voltage; and

FIG. 3 shows an example of a follower assembly that may be used in the circuit of FIG. 2.

### DETAILED DESCRIPTION OF ILLUSTRATIVE EMBODIMENTS

An advantageous feature of some below-described embodiments is to provide a bandgap-type circuit operating under a lower power supply voltage than levels commonly used in the technology for which the circuits are manufactured.

For clarity, the same elements have been designated with the same reference numerals in the different drawings.

The present invention will be described in relation with transistors in CMOS technology. The present invention may however be applied to any other transistor technology or to a combination of different technologies.

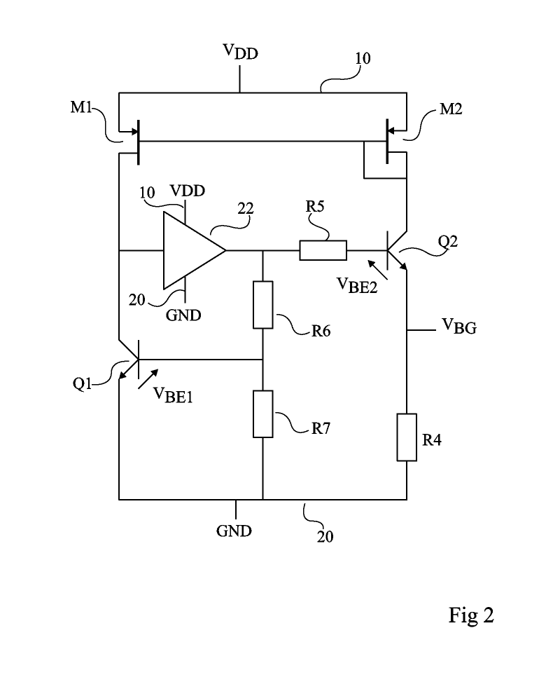

FIG. 2 shows an embodiment of a circuit generating a stable reference voltage. This circuit comprises:
a first current source M1 in series with a first NPN-type bipolar transistor Q1, between a first terminal 10 of application of a positive power supply voltage VDD and a second terminal 20 of application of a reference voltage (typically, ground GND), the emitter being on the side of terminal 10;
a second current source M2 in series with a second bipolar transistor Q2 (NPN-type, with its emitter on the side of terminal 20) and a resistive element R4, between terminals 10 and 20, the junction point of resistive element R4 and of transistor Q2 defining an output terminal of the circuit providing a reference voltage VBG, and the two current sources M1 and M2 being mounted as a current mirror;
a follower assembly 22, in series with an optional resistive element R5, between the collector of transistor Q1 and the base of transistor Q2, the follower assembly being powered by voltage VDD between terminals 10 and 20; and
a resistive dividing bridge formed of resistive elements R6 and R7 in series, between the output terminal of follower assembly 22 and terminal 20, the midpoint of this dividing bridge being connected to the base of transistor Q1.

The circuit shown in FIG. 2 comprises no operational amplifier. The current mirror formed of current sources M1 and M2 enables transistors Q1 and Q2 to conduct the same collector current.

Voltage V_{BG} according to FIG. 2 may be written as:

$${V}_{BG} = {V}_{be 1} + \frac{{R}_{6}}{{R}_{7}} \frac{kT}{q} ln ( p ) ,$$

where R6 and R7 designate the respective values of resistors R6 and R7.

Follower assembly 22, which has an infinite input impedance, transmits the voltage variations and provides the current necessary to drive the base of transistor Q1 without pulling current from current source M1.

Resistive element R5 compensates for the effect of the base current of transistor Q2. The base currents of transistors Q1 and Q2 being equal (due to the two current sources M1 and M2 mounted as a current mirror), the compensation will be perfect if resistances R5 and R6 are equal. Resistive element R4 sets the current in the two branches of the assembly.

An advantage of the assembly of FIG. 2 is that it requires no operational amplifier. The accuracy of the generated reference voltage is thus improved. The implementation of the current mirror has little incidence on the accuracy of the generated reference voltage.

Another advantage of this assembly is that it enables an operation of the circuit with power supply voltages smaller than 1.3 V.

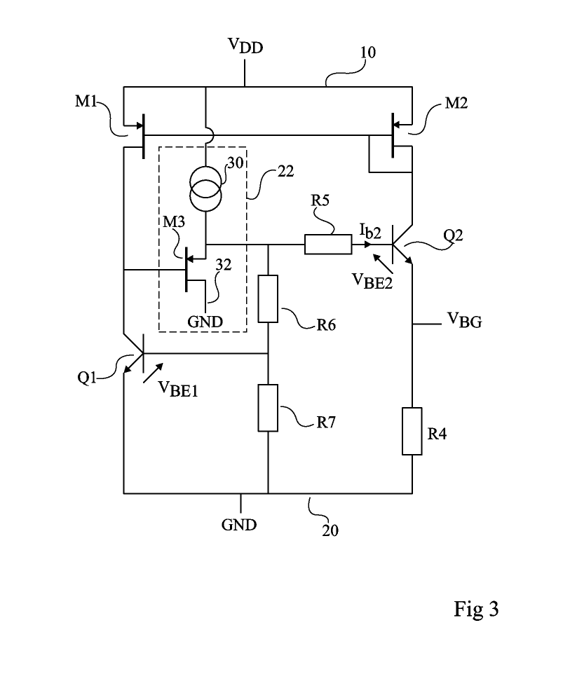

FIG. 3 shows an example of a follower assembly 22 usable in the circuit of FIG. 2. This follower assembly is formed of a current source 30 in series with a MOS transistor M3 between terminals 10 and 20, drain 32 of transistor M3 being coupled to terminal 20 (GND). The junction point of these elements in series defines the output terminal of follower assembly 22.

Minimum voltage Vₘᵢₙ at which the circuit shown in FIG. 3 can be used may be written as:

Vₘᵢₙ=V_{BG}+V_{be2}+V₃₀+R₅*I_{b2},

where V_{BG} stands for the stable reference voltage generated by the circuit, V_{be2} stands for the base-emitter voltage of transistor Q2, V₃₀ stands for the minimum voltage for which current source 30 may be used, R5 designates the value of resistor R5, and I_{b2} stands for the base current of transistor Q2 (current in R5). This current is negligible as compared with the emitter current of Q2.

As a specific embodiment, a circuit such as shown in FIG. 3 can operate with the following values:

V_{BG}=100 mV,

V_{be2}=800 mV.

With a transistor M3 having a 100 mV drain-source voltage, a minimum operating voltage of 1 V, that is, the voltage at which the circuit can be used, is obtained.

The circuit automatically starts as soon as a power supply voltage is applied between terminals 10 and 20. Indeed, a current then immediately starts flowing from source 30 to resistor R5, to thus turn on transistor Q2. This turning-on of transistor Q2 triggers the operation of the current mirror formed of current sources M1 and M2, which results in turning on transistor Q1. An external starting circuit providing a start voltage greater than the operating voltage is thus not necessary.

Specific embodiments have been described. Various alterations, modifications and improvements will occur to those skilled in the art. In particular, although the present invention has been described in relation with examples of circuits formed of NPN bipolar transistors, of resistors, and of current sources, the present invention is applicable to other transistor technologies, for example, PNP bipolar transistors, or to other arrangements of components. For example, the current sources may be resistors or assemblies based on transistors, the transistors may have an N or P channel, the control signals being adapted accordingly.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A circuit for generating a reference voltage, comprising:
a first current source in series with a first bipolar transistor, between a first and a second terminal of application of a power supply voltage;
a second current source in series with a second bipolar transistor and a first resistive element, between said first and second terminals, the junction point of the first resistive element and of the second bipolar transistor defining a third terminal for providing the reference voltage;
a follower assembly having an input terminal connected between the first current source and the first bipolar transistor, and having an output terminal connected to a base of the second bipolar transistor; and
a resistive dividing bridge between the output terminal of the follower assembly and said second terminal, the midpoint of this dividing bridge being connected to a base of the first bipolar transistor.

2. The circuit of claim 1, further comprising a second resistive element interposed between the output terminal of the follower assembly and the base of the second bipolar transistor.

3. The circuit of claim 1, wherein the current sources are formed of MOS transistors mounted as a current mirror.

4. The circuit of claim 1, wherein the collector surface area of the second bipolar transistor (is larger than the collector surface area of the first bipolar transistor.

5. The circuit of claim 1, wherein the follower assembly is formed of a current source in series with a MOS transistor.

6. A circuit for generating a reference voltage comprising:
a first branch including a first current source and a first transistor coupled in series between first and second voltage nodes;
a second branch including a second current source, a second transistor, and a first resistive element coupled in series between the first and second voltage node, wherein the first and second current sources are configured as a current mirror;
a bridge circuit including a follower assembly and a second resistive element coupled in series between the first and second branches; and
a voltage divider coupled between the bridge circuit and the second voltage node.

7. The circuit of claim 6 wherein the first and second current sources comprise a first MOS transistor and a second MOS transistor, respectively.

8. The circuit of claim 6 wherein the follow assembly comprises a current source and a third MOS transistor coupled in series between the first and second voltage nodes.

9. The circuit of claim 6 wherein the first and second transistors each comprises a bipolar transistor.

10. The circuit of claim 9 wherein the second transistor has a collector surface area greater than a collector surface area of the first transistor.

11. The circuit of claim 6 wherein the voltage divider comprises a third and a fourth resistive element connected in series.

12. The circuit of claim 6 wherein the first current source comprises a first MOS transistor and the second current source comprises a second MOS transistor and wherein a gate of the first MOS transistor is tied to a gate of the second MOS transistor.

13. The circuit of claim 6 wherein the bridge circuit is coupled between a junction between the first current source and the first transistor, at one end, and a base of the second transistor, at another end.

14. The circuit of claim 6 further comprising an output voltage node and wherein, for a given voltage on the first voltage node, a voltage on the output voltage node is substantially temperature invariant.

15. A circuit comprising:
a first current source driving a collector of a first transistor;
a second current source driving a collector of a second transistor;
the first current source and the second current source forming a current mirror;
a voltage divider coupled to drive a first base of the first transistor; and
a high input impedance voltage follower being coupled to drive a second base of the second transistor.

16. The circuit of claim 15 further comprising a first resistive element coupled to an emitter of the second transistor and a second resistive element coupled between the high impedance voltage follower and the base of the second resistive element.

17. The circuit of claim 15 wherein the high input impedance voltage follower has an input coupled to the first current source and has a substantially infinite input voltage.

18. The circuit of claim 15 wherein the first current source includes a first MOS transistor and the second current source includes a second MOS transistor.

19. The circuit of claim 18 wherein the high input impedance voltage follower includes a current source coupled in series with a third MOS transistor.

20. The circuit of claim 19 further including a first voltage node and a second voltage node and wherein:
the first MOS transistor and the first transistor are coupled in series between the first and second voltage nodes;
the second MOS transistor and the second transistor are coupled in series between the first voltage node and a first terminal of a first resistive element, a second terminal of the first resistive element being coupled to the second voltage node;
the high impedance voltage follower is coupled between a junction between the first current source and the first transistor, on the one hand, and a first terminal of a second resistive element, a second terminal of the second resistive element being coupled to a base of the second transistor; and
the voltage divider is coupled between an output of the high input voltage follower and the second voltage node.
